(19) United States
(12) Patent Application Publication
(10) Pub. No.: US 2005/0258512 A1
(43) Pub. Date: Nov. 24, 2005

(54) Topographically elevated microelectronic capacitor structure

(75) Inventor: Kuo-Chi Tu, Hsin-Chu (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 10/851,572

(22) Filed: May 21, 2004

(51) Int. Cl. H01L 21/20

(52) U.S. Cl. 257/534

(57) ABSTRACT

A microelectronic product includes a capacitor structure spaced from a contact region within a substrate by a conductor stud layer and an interconnect layer formed upon the conductor stud layer. The interconnect layer may be further spaced from the capacitor structure by a contiguous conductor interconnect and conductor stud layer. The use of the interconnect layer and the contiguous conductor interconnect and conductor stud layer provide for flexible placement of the capacitor structure within the microelectronic product.

### BACKGROUND OF THE INVENTION

1. Field of the Invention

The invention relates generally to capacitor structures within microelectronic products. More particularly, the invention relates to capacitor structures flexibly fabricated within microelectronic products.

2. Description of the Related Art

Capacitors are frequently fabricated within microelectronic products. They serve functions including signal processing functions and data storage functions. Although they are essential within many microelectronic products, they are nonetheless not necessarily readily fabricated with optimal and desirable capacitance within available substrate area, or otherwise optimally spatially placed within available locations within microelectronic products. The invention is directed towards the foregoing object.

### SUMMARY OF THE INVENTION

A first object of the invention is to provide a microelectronic product having a capacitor therein.

A second object of the invention is to provide a microelectronic product in accord with the first object of the invention, where the capacitor may be flexibly placed within the microelectronic product.

In accord with the objects of the invention, the invention provides a microelectronic product having a capacitor formed therein, as well as a method for fabricating the microelectronic product.

The microelectronic product includes a substrate having a contact region formed therein. A first patterned dielectric layer is formed upon the substrate. It has a conductor stud layer formed therethrough and contacting the contact region. A second patterned dielectric layer is formed upon the first patterned dielectric layer. It has a conductor interconnect layer formed therethrough and contacting the conductor stud layer. A first capacitor plate layer is formed upon the conductor interconnect layer. A capacitor dielectric layer is formed upon the first capacitor plate layer. A second capacitor plate layer is formed upon the capacitor dielectric layer.

The invention provides a microelectronic product with a capacitor that may be flexibly fabricated therein. The invention realizes the foregoing object by forming the capacitor in contact with a conductor interconnect layer further in contact with a conductor stud layer within the microelectronic product. The conductor interconnect layer assists in providing a flexible spacing of the capacitor structure within the microelectronic product.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 5 show a series of schematic cross-sectional diagrams illustrating the results of progressive stages of fabricating a microelectronic product in accord with a pair of first embodiments of the invention.

FIG. 6 shows a schematic cross-sectional diagram illustrating the results of fabricating a microelectronic product in accord with a second embodiment of the invention.

FIG. 7 shows a schematic cross-sectional diagram illustrating the results of fabricating a microelectronic product in accord with a third embodiment of the invention.

### DESCRIPTION OF THE PREFERRED EMBODIMENT

The invention provides a microelectronic product having a capacitor that may be flexibly fabricated therein. The invention realizes the foregoing object by forming the capacitor in contact with a conductor interconnect layer further in contact with a conductor stud layer within the microelectronic product. The conductor interconnect layer assists in providing for a flexible spacing of the capacitor within the microelectronic product.

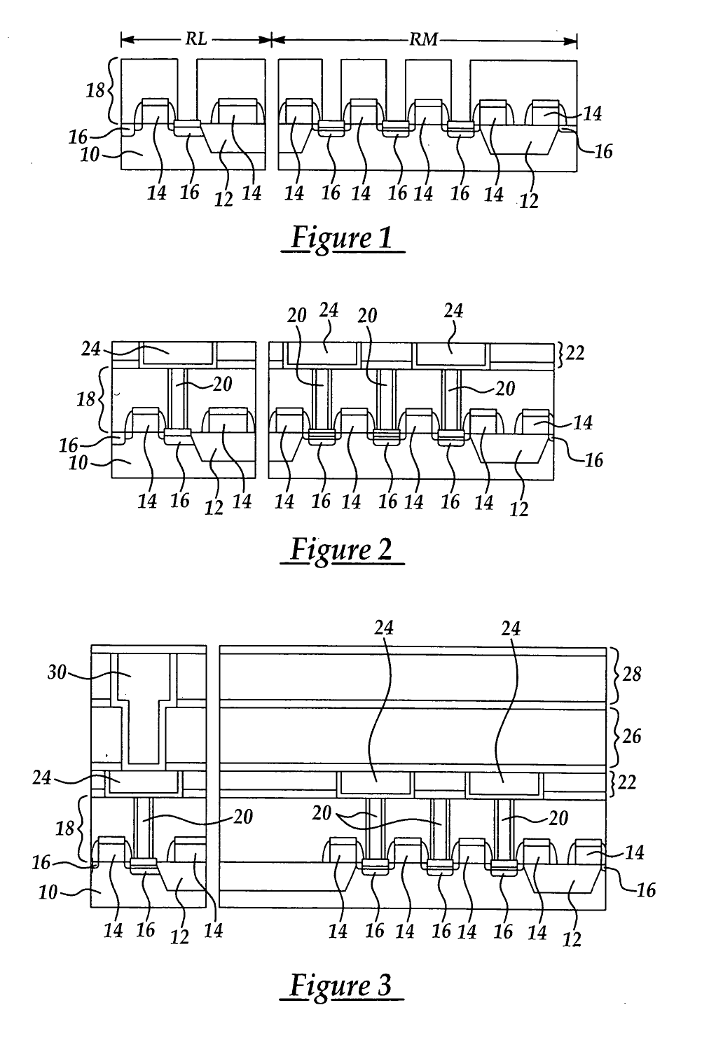

FIG. 1 to FIG. 5 show a series of schematic cross-sectional diagrams illustrating the results of progressive stages in fabricating a microelectronic product in accord with a first embodiment of the invention. FIG. 1 shows a schematic cross-sectional diagram of the microelectronic product at an early stage in its fabrication.

FIG. 1 shows a semiconductor substrate 10 divided into a logic region RL and a memory region RM. A pair of isolation regions 12 is formed into the semiconductor substrate 10 such as to separate a series of active regions of the semiconductor substrate 10.

The semiconductor substrate 10 may be of any of several materials compositions, dopant concentrations and crystallographic orientations as are conventional in the semiconductor product fabrication art. Such material compositions may include bulk semiconductor material compositions (such as bulk silicon, bulk germanium and bulk silicon-germanium alloy semiconductor material compositions) as well as semiconductor-on-insulator semiconductor material compositions. Typically, the semiconductor substrate 10 is a bulk silicon semiconductor substrate. The invention may also be practiced employing substrates such as ceramic substrates.

The isolation regions 12 may be formed as shallow trench isolation regions, deep trench isolation regions or local oxidation of silicon isolation regions as are otherwise generally conventional in the semiconductor product fabrication art. Typically, the series of isolation regions 12 is formed as shallow trench isolation regions.

A series of gate electrode stacks 14 is formed upon the active regions separated by the isolation regions 12, as well as upon the isolation regions 12 themselves. Gate electrode stacks 14 when formed upon active regions provide field effect transistor devices and gate electrode stacks 14 when formed upon isolation regions 12 provide interconnect structures. The gate electrode stacks 14 include gate dielectric layers formed upon the active regions of the semiconductor substrate, gate electrodes formed aligned thereupon and spacer layers formed at opposite sidewalls adjoining thereto. Each of the gate dielectric layers, gate electrodes and spacer layers may be formed employing methods and materials as are otherwise conventional in the semiconductor product fabrication art. Gate dielectric layers are typically silicon oxide materials formed to a thickness of from about 10 to about 200 angstroms. Gate electrodes are typically formed of polysilicon or a polycide (polysilicon/metal silicide stack) formed to a thickness of from about 1500 to about 3000 angstroms. Spacers are typically formed employing an anisotropic etching method. A series of source/drain regions 16 is formed into the active regions of the semiconductor substrate 10 at locations separated by the series of gate electrode stacks 14. The series of source/drain regions 16 is also formed employing methods and materials as are conventional in the semiconductor product fabrication art. The methods are typically ion implant methods.

Finally, FIG. 1 shows a series of patterned first dielectric layers 18 covering in general the series of gate electrode stacks 14 and providing access to the series of source/drain regions 16 through a series of first apertures. The series of patterned first dielectric layers 18 may be formed of an oxide dielectric material as suggested in FIG. 1. In the alternative, the series of patterned first dielectric layers 18 may be formed of other dielectric materials as are also conventional in the semiconductor product fabrication art.

FIG. 2 shows a series of conductor stud layers 20 formed into the series of first apertures. The series of conductor stud layers 20 is typically formed employing a barrier material layer that surrounds a core material layer formed of a copper, copper alloy, tungsten or tungsten alloy core material. Typically, each of the series of conductor stud layers 20 is formed to a thickness of from about 1000 to about 8000 angstroms.

FIG. 2 also shows a series of patterned second dielectric layers 22 formed upon the series of patterned first dielectric layers 18. A series of patterned interconnect layers 24 is formed interposed between the series of patterned second dielectric layers 22.

The series of patterned second dielectric layers, as well as subsequent patterned dielectric layers, is generally intended as being formed as a laminate that includes a dielectric bulk layer formed upon a dielectric stop layer. The dielectric bulk layer may be formed of dielectric materials analogous, equivalent or identical to the dielectric materials employed for forming the patterned first dielectric layers 18. The dielectric stop layer will typically be formed of a silicon nitride, silicon carbide or silicon oxynitride dielectric stop material.

The series of patterned interconnect layers 24 is typically formed of a copper or copper alloy conductor material nested within a barrier material layer. The barrier material may be selected from the group including but not limited to titanium, tantalum and tungsten barrier materials, and nitrides thereof. Typically, the series of patterned interconnect layers 24 is formed to a thickness of from about 1000 to about 5000 angstroms.

FIG. 3 shows the addition of a patterned third dielectric layer 26 formed upon the semiconductor product of FIG. 2. A patterned fourth dielectric layer 28 is formed upon the patterned third dielectric layer 26. The patterned fourth dielectric layer 28 and the patterned third dielectric layer 26 may be formed employing methods and materials analogous or equivalent to the methods and materials employed for forming the patterned second dielectric layer 22.

Also shown within FIG. 3, and formed through the patterned fourth dielectric layer 28 and the patterned third dielectric layer 26 is a first contiguous conductor interconnect and conductor stud layer 30. The first contiguous conductor interconnect and conductor stud layer is formed employing a dual damascene method while underlying conductor layers as discussed above are formed employing a single damascene method. It will typically be formed of a copper core layer nested within a barrier material layer. Typically, the first contiguous conductor interconnect and conductor stud layer 30 is formed to a thickness of from about 5000 to about 20000 angstroms.

FIG. 4 and FIG. 5 show a pair of separate embodiments resulting from further processing of the semiconductor product of FIG. 3. Each of FIG. 4 and FIG. 5 show a capacitor structure 32 including in layered sequence a lower capacitor plate layer, a capacitor dielectric layer and an upper capacitor plate layer. The capacitor structure may be a metal-insulator-metal (MIM) capacitor structure. Typically, the capacitor dielectric layer is formed to a thickness of from about 20 to about 200 angstroms. The capacitor structure 32 is formed into a pair of second apertures to allow contact of the capacitor structure 32 with the pair of patterned interconnect layers 24. Thus, the capacitor structure 32 is spaced from a pair of conductor stud layers 20 by a pair of conductor interconnect layers 24. Such spacing allows flexibility of placement of the capacitor structure within the semiconductor products of FIG. 4 and FIG. 5.

FIG. 4 and FIG. 5 also show a fifth dielectric layer 34 passivating the capacitor structure 32. A sixth dielectric layer 36 is formed upon the fifth dielectric layer 34. A pair of second patterned conductor interconnect and conductor stud layers 38 is formed through the sixth dielectric layer 36 and the fifth dielectric layer 34. One contacts the upper capacitor plate layer within the capacitor structure 32 and the other contacts the first patterned conductor interconnect and conductor stud layer 30 within the logic region of the semiconductor substrate 10. FIG. 4 and FIG. 5 differ with respect to the presence or absence of a stop layer upon the fourth dielectric layer 28 and beneath the lower capacitor plate layer of the capacitor structure 32.

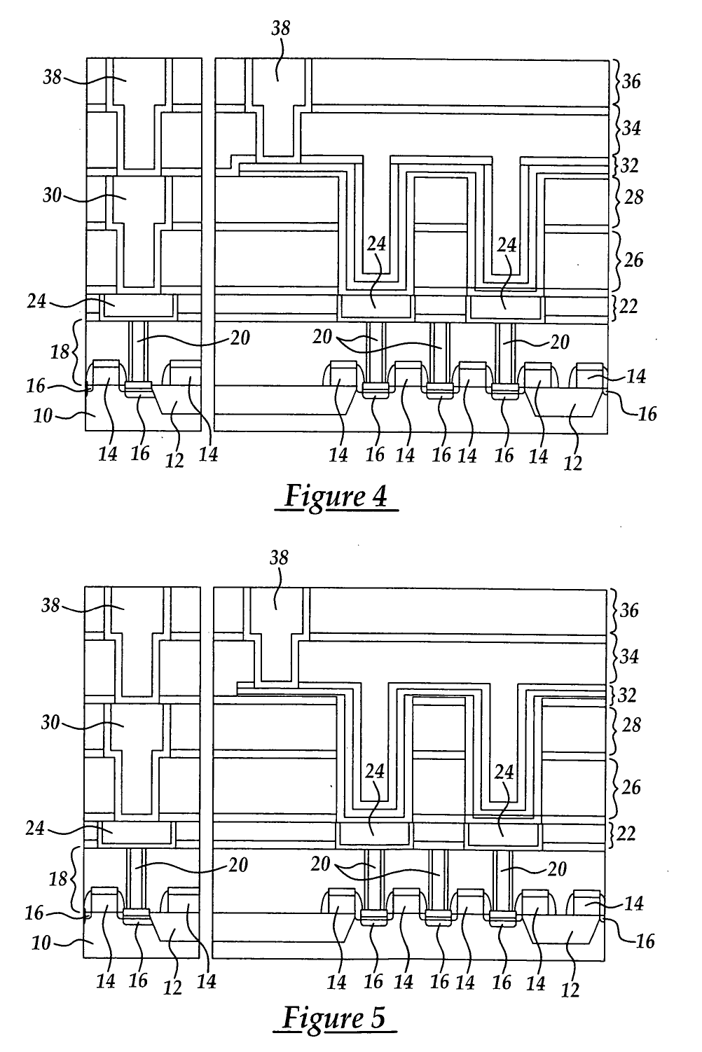

FIG. 6 shows a schematic cross-sectional diagram illustrating a semiconductor product in accord with a second preferred embodiment of the invention. The semiconductor product is related to the semiconductor product of the first preferred embodiment of the invention, but with the capacitor structure further spaced from the pair of interconnect layers 24 by an additional pair of patterned first conductor interconnect and conductor stud layers 30. In FIG. 6, a substrate 10′ is intended to include all layers 10-20 as illustrated in FIG. 2. To accommodate this additional spacing, the semiconductor product employs a seventh dielectric layer 40 and an eighth dielectric layer 42, as well as a pair of third patterned conductor interconnect and conductor stud layers 44. Thus, a semiconductor product in accord with the second preferred embodiment of the invention provides an alternative spacing and placement of a capacitor structure within a semiconductor product in accord with the invention.

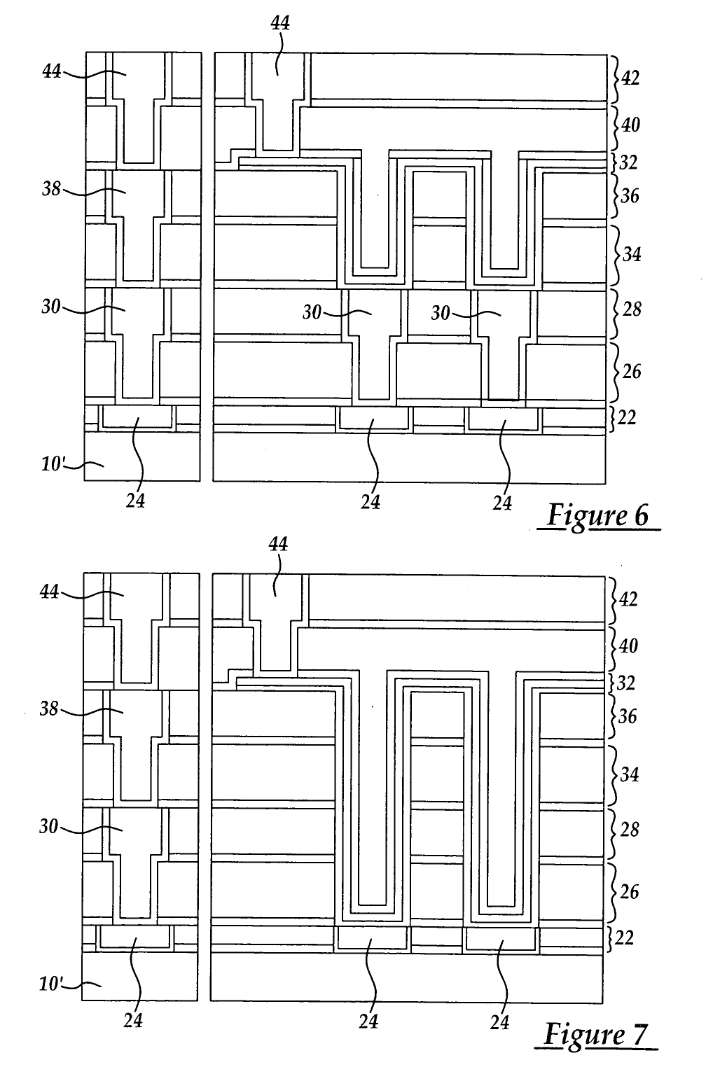

FIG. 7 shows a schematic cross-sectional diagram illustrating a semiconductor product in accord with a third preferred embodiment of the invention. In comparison with the semiconductor product of FIG. 6, the semiconductor product of FIG. 7 provides for a larger capacitor structure 32 that penetrates through four dielectric layers rather than two.

The preferred embodiments of the invention provide a series of capacitor structures for use in general within microelectronic products, and more specifically within semiconductor products. The capacitor structures are flexibly placed within the semiconductor products incident to being spaced from a conductor stud layer by at least a single conductor interconnect layer.

The preferred embodiments of the invention are illustrative of the invention rather than limiting of the invention. Revisions and modifications may be made to methods, materials, structures and dimensions in accord with the preferred embodiments of the invention while providing additional embodiments of the invention, further in accord with the accompanying claims.

1. A microelectronic product comprising:
a substrate having a contact region formed therein;
a first patterned dielectric layer formed upon the substrate and having a conductor stud layer formed therethrough and contacting the contact region;
a second patterned dielectric layer formed upon the first patterned dielectric layer and having a conductor interconnect layer formed therethrough and contacting the first conductor stud layer;
a first capacitor plate layer formed upon the conductor interconnect layer;
a capacitor dielectric layer formed upon the first capacitor plate layer; and
a second capacitor plate layer formed upon the capacitor dielectric layer.

2. The microelectronic product of claim 1 wherein the contact region is a conductor contact region.

3. The microelectronic product of claim 1 wherein the contact region is a semiconductor contact region.

4. The microelectronic product of claim 1 wherein the conductor stud layer is formed to a thickness of from about 1000 to about 8000 angstroms.

5. The microelectronic product of claim 1 wherein the conductor interconnect layer is formed to a thickness of from about 1500 to about 2500 angstroms.

6. The microelectronic product of claim 1 wherein the capacitor dielectric layer is formed to a thickness of from about 20 to about 200 angstroms.

7. A microelectronic product comprising:
a substrate having a contact region formed therein;
a first patterned dielectric layer formed upon the substrate and having a first conductor stud layer formed therethrough and contacting the contact region;
a second patterned dielectric layer formed upon the first patterned dielectric layer and having a conductor interconnect layer formed therethrough and contacting the first conductor stud layer;
at least a third patterned dielectric layer formed upon the second patterned dielectric layer and having a contiguous conductor interconnect and conductor stud layer formed therethrough and contacting the conductor interconnect layer;
a first capacitor plate layer formed upon the contiguous conductor interconnect and conductor stud layer;
a capacitor dielectric layer formed upon the first capacitor plate layer; and
a second capacitor plate layer formed upon the capacitor dielectric layer.

8. The microelectronic product of claim 7 wherein the contact region is a conductor contact region.

9. The microelectronic product of claim 7 wherein the contact region is a semiconductor contact region.

10. The microelectronic product of claim 7 wherein the conductor stud layer is formed to a thickness of from about 1000 to about 8000 angstroms.

11. The microelectronic product of claim 7 wherein the conductor interconnect layer is formed to a thickness of from about 1000 to about 5000 angstroms.

12. The microelectronic product of claim 7 wherein the contiguous conductor interconnect and conductor stud layer is formed to a thickness of from about 5000 to about 20000 angstroms.

13. The microelectronic product of claim 7 wherein the capacitor dielectric layer is formed to a thickness of from about 20 to about 200 angstroms.

14. A semiconductor product comprising:
a semiconductor substrate having a logic region having a first contact region formed therein and a memory region having a second contact region formed therein;
a first patterned dielectric layer formed upon the semiconductor substrate and having a first conductor stud layer formed therethrough and contacting the first contact region and a second conductor stud formed therethrough and contacting the second contact region;
a second patterned dielectric layer formed upon the first patterned dielectric layer and having a first conductor interconnect layer formed therethrough and contacting the first conductor stud layer and a second conductor interconnect layer formed therethrough and contacting the second conductor stud layer;
at least a third patterned dielectric layer formed upon the second patterned dielectric layer and having a contiguous conductor interconnect and conductor stud layer formed therethrough and contacting the first conductor interconnect layer and a capacitor structure formed therethrough and contacting the second conductor interconnect layer.

15. The microelectronic product of claim 14 wherein each of the first and second conductor stud layers is formed to a thickness of from about 1000 to about 8000 angstroms.

16. The microelectronic product of claim 14 wherein each of the conductor interconnect layers is formed to a thickness of from about 1000 to about 5000 angstroms.

17. The microelectronic product of claim 14 wherein the contiguous conductor interconnect and conductor stud layer is formed to a thickness of from about 8000 to about 15000 angstroms.

18. The microelectronic product of claim 14 wherein the capacitor dielectric layer is formed to a thickness of from about 20 to about 200 angstroms.

19. The microelectronic product of claim 14 further comprising a second contiguous conductor interconnect and conductor stud layer interposed between the second interconnect and the capacitor structure.

20. The microelectronic product of claim 14 wherein the capacitor structure is a metal-insulator-metal capacitor structure.
